(19) United States
(12) Patent Application Publication
(10) Pub. No.: US 2020/0258769 A1
(43) Pub. Date: Aug. 13, 2020

(54) SEMICONDUCTOR MANUFACTURING DEVICE MEMBER, METHOD FOR MANUFACTURING THE SAME, AND FORMING DIE

(71) Applicant: NGK INSULATORS, LTD., Nagoya-City (JP)

(72) Inventors: Kazuhiro NOBORI, Handa-City (JP); Takuji KIMURA, Kariya-City (JP)

(73) Assignee: NGK INSULATORS, LTD., Nagoya-City (JP)

(21) Appl. No.: 16/864,282

(22) Filed: May 1, 2020

Related U.S. Application Data
(63) Continuation of application No. PCT/JP2018/040588, filed on Oct. 31, 2018.

(30) Foreign Application Priority Data
Nov. 2, 2017 (JP) 2017-212932

(51) Int. Cl. H01L 21/687; B28B 1/14; B28B 7/00; H01L 21/3065; H01L 21/67; C04B 37/00

(52) U.S. Cl. CPC H01L 21/68792; B28B 1/14; C04B 37/00; H01L 21/3065; H01L 21/67098; B28B 7/00

(57) ABSTRACT

A semiconductor manufacturing device member according to the present invention includes a ceramic disc with an internal electrode and a ceramic shaft that supports the disc. The disc and the shaft are integrated without having a bonding interface.

### BACKGROUND OF THE INVENTION

### 1. Field of the Invention

The present invention relates to a semiconductor manufacturing device member, a method for manufacturing the same, and a forming die.

### 2. Description of the Related Art

To date, semiconductor manufacturing device members, for example, a ceramic heater including a ceramic disc with an internal electrode and a ceramic shaft that supports the disc, are known. Regarding production of such a semiconductor manufacturing device member, it is known that the disc and the shaft are produced by being separately fired, and, thereafter, they are bonded by heat treatment while being in contact with each other, as described in, for example, PTL 1.

### CITATION LIST

### Patent Literature

PTL 1: Japanese Unexamined Patent Application Publication No. 2006-232576

### SUMMARY OF THE INVENTION

However, if the disc and the shaft which have been fired once are heat-treated for the purpose of bonding, growth of sintered particles is facilitated due to undergoing heat history twice. As a result, there are problems of the strength of the disc or the shaft being degraded and, in some rare cases, peeling occurring at the bonding interface.

The present invention was realized to address such problems, and it is a main object to enhance the strength of a semiconductor manufacturing device member and to suppress peeling between a disc and a shaft from occurring.

A semiconductor manufacturing device member according to the present invention includes
a ceramic disc with an internal electrode and a ceramic shaft that supports the disc,
wherein the disc and the shaft are integrated without having a bonding interface.

In the semiconductor manufacturing device member, since the disc and the shaft are integrated without having a bonding interface, peeling at a bonding interface does not occur. Meanwhile, regarding such a semiconductor manufacturing device member, the integrated formed body of the disc and the shaft can be produced by performing firing only once (by undergoing heat history once). Consequently, growth of sintered particles can be suppressed compared with the case of undergoing heat history twice, and, as a result, the strength can be enhanced.

In the semiconductor manufacturing device member according to the present invention, the electrode may be at least one of a heater electrode, an RF electrode, and an electrostatic electrode. It is preferable that such an electrode be parallel to the plate surface of the disc.

In the semiconductor manufacturing device member according to the present invention, the disc may have a gas channel that opens on the side surface of the disc and that is formed in the plate surface direction of the disc, and the shaft may have a gas feed passage that extends in the vertical direction and that feeds gas to the gas channel. Ejecting the gas from the opening of the gas channel to the side surface of the disc through the gas feed passage can suppress accumulations from adhering to the lower surface of the disc.

In the semiconductor manufacturing device member according to the present invention, a boundary portion between the outer surface of the shaft and the surface of the disc with which the shaft is integrated may be an R-surface or a tapered surface. As a result, stress applied to the boundary portion can be relaxed.

In the semiconductor manufacturing device member according to the present invention, the shaft may be a cylindrical member, and a boundary portion between the inner surface of the shaft and the surface of the disc with which the shaft is integrated is an R-surface or a tapered surface. As a result, stress applied to the boundary portion can be relaxed.

A forming die according to the present invention is
a forming die used for producing the above-described semiconductor manufacturing device member and includes
a disc-forming portion that is a space to form a disc lower layer on the shaft side of the disc, and
a shaft-forming portion that is in communication with the disc-forming portion and that is a space to form the shaft.

In the forming die, the disc-forming portion is in communication with the shaft-forming portion. Consequently, when a ceramic slurry containing a ceramic raw material powder and a molding agent is injected into the forming die, both the disc-forming portion and the shaft-forming portion are filled with the ceramic slurry. Thereafter, a base formed body in which an unfired disc lower layer formed in the disc-forming portion and an unfired shaft formed in the shaft-forming portion are integrated in a seamless state can be formed by the molding agent undergoing a chemical reaction in the forming die so as to make the ceramic slurry into a mold. When the resulting base formed body is fired, the semiconductor manufacturing device member is obtained by performing firing once. Meanwhile, firing may be performed after an electrode (or an electrode precursor) and a disc formed body are further stacked on the unfired disc lower layer of the base formed body. In such a case, the semiconductor manufacturing device member is also obtained by performing firing once.

In the forming die according to the present invention, a boundary portion between the disc-forming portion and the shaft-forming portion may be an R-surface or a tapered surface.

In the forming die according to the present invention, the disc-forming portion is a space surrounded by a pair of circular surfaces and an outer circumferential surface connected to the pair of circular surfaces, and the shaft-forming-portion-side circular surface of the pair of circular surfaces may be a depressed surface that is depressed toward the shaft-forming portion and the circular surface opposite to the shaft-forming portion of the pair of circular surfaces may be a protruding surface that protrudes toward the shaft-forming portion. Consequently, when the base formed body in which the unfired disc lower layer and the unfired shaft are integrated in a seamless state is supported in an orientation with the unfired shaft at the bottom and with the unfired disc lower layer at the top, the unfired disc lower layer has a shape in which the outer circumferential edge warps upward relative to the center portion. When the base formed body is fired, the disc lower layer after firing becomes an almost flat plane by performing firing in the orientation with the unfired shaft at the top and with the unfired disc lower layer at the bottom. Regarding each of the depressed surface and the protruding surface, the height difference d between the center position and the position 150 mm distant from the center position outward in the radial direction is preferably 0.7 mm or more and 2.6 mm or less, or the inclination angle 0 of each of the depressed surface and the protruding surface is preferably 0.25°≤θ≤1°. Consequently, the disc lower layer after firing becomes a flatter plane. In this regard, firing may be performed after an electrode (or an electrode precursor) and a disc formed body are further stacked on the unfired disc lower layer of the base formed body. In such a case, each of the disc lower layer, the electrode, and the disc after firing becomes a flat plane.

In the forming die according to the present invention, the depressed surface may be a surface that is depressed toward the shaft-forming portion in the form of a circular cone or a circular truncated cone, and the protruding surface may be a surface that protrudes toward the shaft-forming portion in the form of a circular cone or a circular truncated cone. Alternatively, each of the depressed surface and the protruding surface may be a curved surface.

A method for manufacturing a semiconductor manufacturing device member according to the present invention includes the steps of

(a) producing, by using the above-described forming die, a base formed body in which an unfired disc lower layer formed in the disc-forming portion and an unfired shaft formed in the shaft-forming portion are integrated in a seamless state by using a mold-casting method,

(b) obtaining a final formed body by stacking an unfired disc upper layer provided with an electrode or a precursor of the electrode parallel to the unfired disc lower layer on the upper surface of the unfired disc lower layer of the base formed body, and

(c) obtaining a semiconductor manufacturing device member in which the disc and the shaft are integrated without having a bonding interface by calcining the final formed body, and, thereafter, firing the resulting final formed body in the state of being mounted with the unfired disc upper layer at the bottom and with the unfired shaft at the top on a horizontal support surface.

According to the method for manufacturing a semiconductor manufacturing device member, a semiconductor manufacturing device member in which the disc and the shaft are integrated without having a bonding interface can be obtained. Since such a semiconductor manufacturing device member can be produced by firing the final feinted body only once (by subjecting to heat history once), growth of sintered particles can be suppressed compared with the case in which the disc and the shaft are fired twice, and, as a result, the strength can be enhanced.

Here, “mold-casting method” denotes a method in which a ceramic slurry containing a ceramic raw material powder and a molding agent is injected into the forming die and the molding agent undergoes a chemical reaction in the forming die to make the ceramic slurry into a mold so as to obtain a formed body. For example, the molding agent may include an isocyanate and a polyol so that molding is caused by a urethane reaction. The “precursor of an electrode” denotes a material that becomes an electrode by being fired and is, for example, a layer coated or printed with an electrode paste in the form of an electrode.

In the method for manufacturing a semiconductor manufacturing device member according to the present invention, when the forming die in which a pair of circular surfaces constituting the disc-forming portion are the above-described depressed surface and protruding surface is used, the base formed body in which the unfired disc lower layer and the unfired shaft are integrated in a seamless state while being supported in an orientation with the unfired shaft at the bottom and with the unfired disc lower layer at the top makes the disc lower layer to have a shape in which the outer circumferential edge warps upward relative to the center portion. The disc after firing becomes an almost flat plane by supporting and firing the final formed body in the orientation with the unfired shaft at the top during the firing step. Meanwhile, in the mold-casting method, gas may be generated when the molding agent undergoes a chemical reaction in the forming die. The resulting gas tends to be discharged to the outside along the depressed surface. Consequently, gas bubbles hardly remain in the base formed body. In particular, regarding each of the depressed surface and the protruding surface, it is preferable that the height difference d be specified to be 0.7 mm or more and 2.6 mm or less or that the inclination angle θ be specified to be 0.25≤θ≤1° because the disc lower layer after firing becomes a flatter plane.

Regarding the method for manufacturing a semiconductor manufacturing device member according to the present invention, in step (a) above, a gas channel may be formed on the upper surface of the unfired disc lower layer so as to open on the side surface during production of the base formed body by using the mold casting method, and in step (b) above, the final formed body may be obtained by bonding the unfired disc upper layer above the gas channel. Consequently, a semiconductor manufacturing device member including a gas channel that opens on the side surface of the disc and that is formed in the plate surface direction of the disc can be obtained.

Regarding the method for manufacturing a semiconductor manufacturing device member according to the present invention, in step (c) above, firing may be performed in the state in which a weight is placed on the unfired disc lower layer of the final formed body after being calcined. Consequently, the disc of the ceramic heater obtained after firing becomes flatter and, in addition, deformation is further suppressed.

### BRIEF DESCRIPTION OF THE DRAWINGS

FIG. 1 is a perspective view of a ceramic heater 10.

FIG. 2 is a sectional view cut along line A-A in FIG. 1 (vertical sectional view).

FIG. 3 is a vertical sectional view of a base formed body 30.

FIG. 4 is a vertical sectional view of a forming die 40.

FIGS. 5A to 5J are a forming flow diagram of production of a final formed body 50.

FIGS. 6A and 6B are a firing flow diagram of obtaining the ceramic heater 10 by firing a calcined body 60.

FIG. 7 is a perspective view of a ceramic heater 110.

FIG. 8 is a sectional view cut along line B-B in FIG. 7.

FIGS. 9A to 9D are a forming flow diagram of production of a final formed body 150.

FIGS. 10A and 10B are a firing flow diagram of obtaining a ceramic heater 110 by firing a calcined body 160.

FIG. 11 is a vertical sectional view of a modified example of the ceramic heater 10.

FIG. 12 is a vertical sectional view of a modified example of the ceramic heater 10.

FIG. 13 is an SEM image of a ceramic heater 10 of experimental example A9.

FIG. 14 is an SEM image of a ceramic heater of experimental example A9.

### DETAILED DESCRIPTION OF THE INVENTION

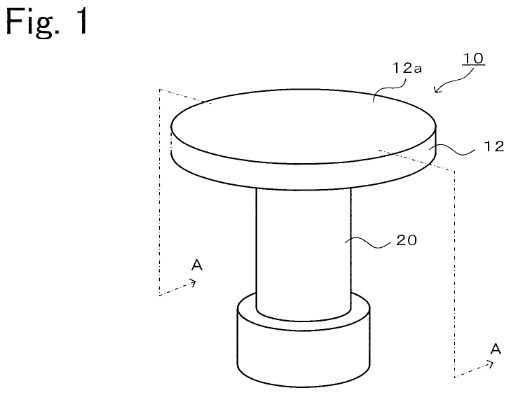

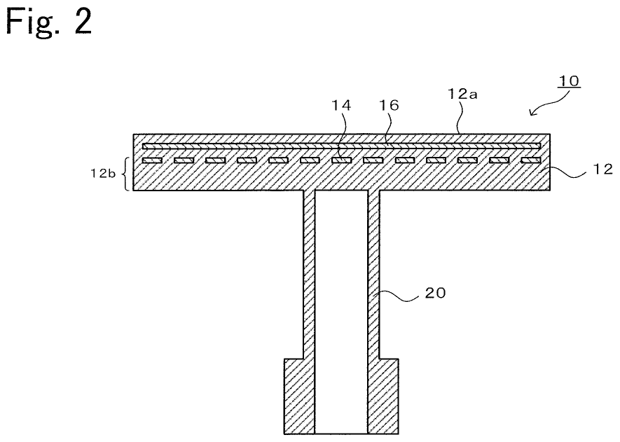

A preferred embodiment according to the present invention will be described below with reference to the drawings. FIG. 1 is a perspective view of a ceramic heater 10. FIG. 2 is a sectional view cut along line A-A in FIG. 1.

As shown in FIG. 1, the ceramic heater 10 is a type of semiconductor manufacturing device member in which a disc 12 and a shaft 20 that are formed of the same ceramic material are integrated without having a bonding interface.

As shown in FIG. 2, the disc 12 includes a heater electrode 14 and an RF electrode 16. The upper surface of the disc 12 is a wafer placement surface 12a, and a silicon wafer to be subjected to plasma treatment is mounted. The heater electrode 14 and the RF electrode 16 are substantially parallel to the wafer placement surface 12a. The heater electrode 14 is composed of, for example, a conductive coil that is wired in a unicursal manner across the surface of the disc. A terminal rod (not shown in the drawing) is connected to each end of the heater electrode 14, and heat is generated by applying a voltage through the heater terminal rods. The RF electrode 16 is a circular thin layer electrode having a somewhat smaller radius than the disc 12 and is formed from, for example, a mesh sheet in which thin metal wires are woven into the shape of a net. The RF electrode 16 is embedded between the heater electrode 14 and the wafer placement surface 12a in the disc 12. Power feed rods (not shown in the drawing) are connected to the RF electrode 16, and an alternating-current high-frequency voltage is applied through the power feed rods. In this regard, it is preferable that the material for forming the heater electrode 14 and the RF electrode 16 have a thermal expansion coefficient close to the thermal expansion coefficient of the ceramic material used for the disc 12 in consideration of preventing cracking in the disc 12 from occurring during production.

The shaft 20 is integrated with the lower surface of the disc 12 without having a bonding interface and supports the disc 12.

Next, an application example of the ceramic heater 10 will be described. The ceramic heater 10 is arranged in a chamber not shown in the drawing, and a wafer is placed on the wafer placement surface 12a. Subsequently, an alternating-current high-frequency voltage is applied to the RF electrode 16 and, thereby, plasma is generated between parallel plate electrodes composed of a horizontal counter electrode, although not shown in the drawing, disposed in an upper portion of the chamber and the RF electrode 16 embedded in the disc 12. The resulting plasma is used, and the wafer is subjected to CVD film formation, etching, or the like. Meanwhile, the temperature of the wafer is determined on the basis of a detection signal of a thermocouple not shown in the drawing, and the voltage applied to the heater electrode 14 is controlled so that the temperature becomes a predetermined temperature (for example, 350° C. or 300° C.)

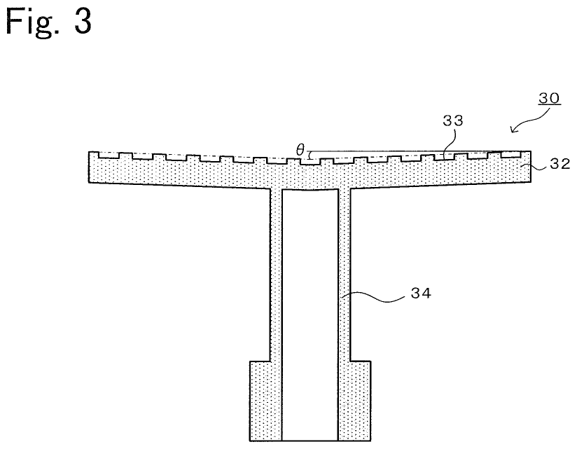

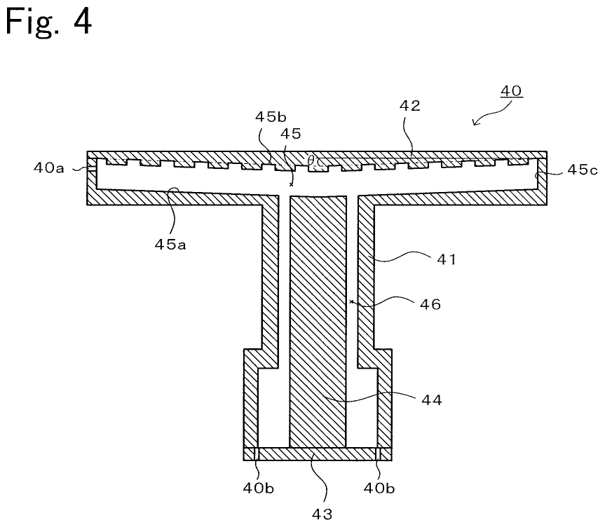

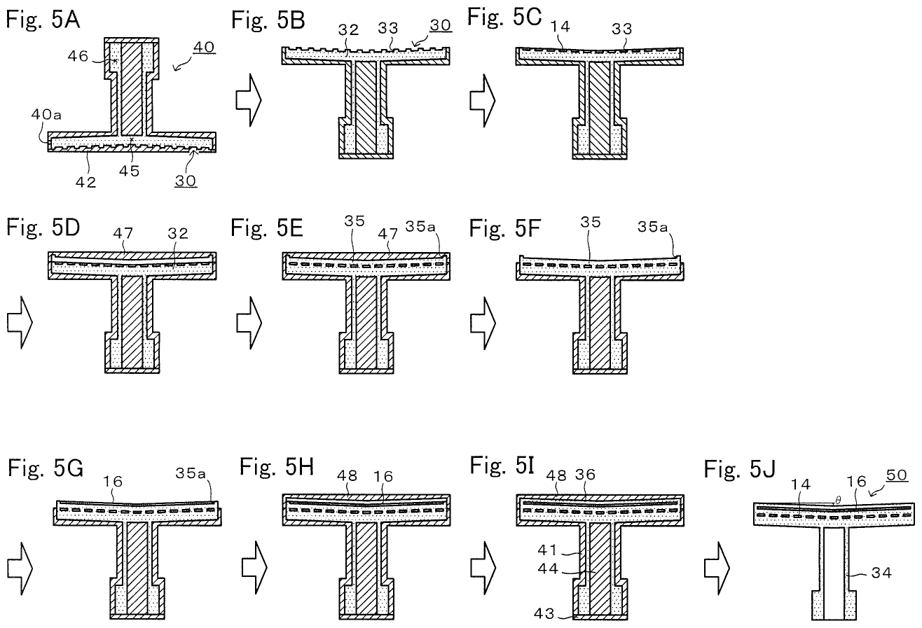

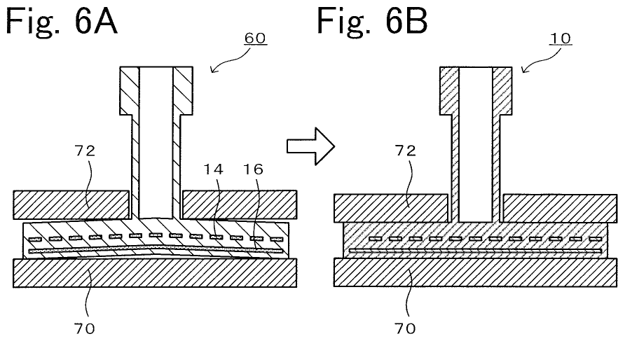

Next, a production example of the ceramic heater 10 will be described. FIG. 3 is a vertical sectional view of the base formed body 30. FIG. 4 is a vertical sectional view of a forming die 40. FIGS. 5A to 5J are a forming flow diagram of production of a final formed body 50. FIGS. 6A and 6B are a firing flow diagram of obtaining the ceramic heater 10 by firing a calcined body 60.

1. Forming step

The base formed body 30 used to produce the ceramic heater 10 is produced. As shown in FIG. 3, in the base formed body 30, the unfired disc lower layer 32 and the unfired shaft 34 are integrated in a seamless state. The unfired disc lower layer 32 is a formed body corresponding to the shaft-side disc lower layer 12b (refer to FIG. 2) rather than to the upper surface of the heater electrode 14 in the disc 12, and the unfired shaft 34 is a formed body corresponding to the shaft 20. A heater electrode groove 33 into which the heater electrode 14 is fit is formed on the upper surface of the unfired disc lower layer 32. The unfired disc lower layer 32 has a shape in which the outer circumferential edge warps upward relative to the center portion. Specifically, the upper surface of the unfired disc lower layer 32 is a depressed surface that is depressed toward the unfired shaft 34 in the form of a circular cone, and the lower surface is a protruding surface that protrudes toward the unfired shaft 34 in the form of a circular cone. Regarding each of the upper surface and the lower surface of the unfired disc lower layer 32, the height difference d between the center position and the position 150 mm distant from the center position outward in the radial direction is preferably 0.7 mm or more and 2.6 mm or less, or the inclination angle θ that is formed by a line segment bonding the center portion to the outer circumferential edge and a horizontal plane is a predetermined angle within the range of preferably 0.25° or more and 1° or less.

To produce the base formed body 30, the forming die 40 for forming the base formed body 30 is prepared. As shown in FIG. 4, the forming die 40 is composed of a die main body 41, a first lid 42, a bottom plate 43, and a circular column 44. The internal space of the forming die 40 is composed of a disc-forming portion 45 and a shaft-forming portion 46. The die main body 41 is a portion that delimits the outer circumferential surface of the base formed body 30, the first lid 42 is a portion that delimits the upper surface of the unfired disc lower layer 32 of the base formed body 30, the bottom plate 43 is a portion that delimits the lower surface of the unfired shaft 34 of the base formed body 30, and the circular column 44 is a portion that delimits a hollow portion of the unfired shaft 34. In this regard, the disc-forming portion 45 is a space for forming the unfired disc lower layer 32 and, therefore, is also referred to as a space for forming the disc lower layer 12b. The disc-forming portion 45 is a space surrounded by a pair of circular surfaces 45a and 45b and an outer circumferential surface 45c connected to the pair of circular surfaces 45a and 45b. The shaft-forming-portion-46-side circular surface 45a of the pair of circular surfaces 45a and 45b is a depressed surface that is depressed toward the shaft-forming portion 46. The circular surface 45b opposite to the shaft-forming portion 46 is a protruding surface that protrudes toward the shaft-forming portion 46. Regarding each of the circular surface 45a that is the depressed surface and the circular surface 45b that is the protruding surface, the height difference d between the center position and the position 150 mm distant from the center position outward in the radial direction is preferably 0.7 mm or more and 2.6 mm or less. Meanwhile, the inclination angle θ of each of the circular surface 45a and the circular surface 45b is preferably 0.25°≤1°. An example of the relationship between the inclination angle θ and the height difference d is shown in Table 1 below. The circular surface 45b has a shape capable of forming the heater electrode groove 33 of the unfired disc lower layer 32 of the base formed body 30. In the forming die 40, a slurry injection port 40a is formed to open on the outer circumferential surface 45c of the disc-forming portion 45, and discharge ports 40b are disposed in the bottom plate 43 of the shaft-forming portion 46. In this regard, the circular surface 45a that is the depressed surface may be a surface depressed in the form of a circular cone or a circular truncated cone or may be a surface curved into a depressed form. Meanwhile, the circular surface 45b that is the protruding surface may be a surface protruding in the form of a circular cone or a circular truncated cone or may be a surface curved into a protruding form.

TABLE 1

| θ (°) | tan θ | d^{※} (mm) |
|---|---|---|
| 0.25 | 0.004 | 0.7 |
| 1 | 0.017 | 2.6 |

^{※}d is a height difference between a center position of a circular surface and a position 150 mm distant from a center position outward in a radial direction

As shown in FIG. 5A, the forming die 40 is arranged with the disc-forming portion 45 at the bottom and with the shaft-forming portion 46 at the top, the entire disc-forming portion 45 and the entire shaft-forming portion 46 are filled with a ceramic slurry that is injected through the injection port 40a, and the slurry is cured so as to obtain the base formed body 30. The specific procedure is as described below.

A ceramic slurry precursor is produced by adding a solvent and a dispersing agent to a ceramic powder and by performing mixing. A ceramic material used as the ceramic powder may be an oxide-based ceramic or a non-oxide-based ceramic. For example, alumina, yttria, aluminum nitride, silicon nitride, silicon carbide, samaria, magnesia, magnesium fluoride, and ytterbium oxide may be used. One of these materials may be used alone, or at least two may be used in combination. In this regard, there is no particular limitation regarding the particle diameter of the ceramic material provided that a slurry can be prepared or produced. There is no particular limitation regarding the solvent provided that dispersing agents, isocyanates, polyols, and catalysts are dissolved. Examples of the solvent include hydrocarbon solvents (toluene, xylene, solvent naphtha, and the like), ether solvents (ethylene glycol monoethyl ether, butyl carbitol, butyl carbitol acetate, and the like), alcohol solvents (isopropanol, 1-butanol, ethanol, 2-ethylhexanol, terpineol, ethylene glycol, glycerin, and the like), ketone solvents (acetone, methyl ethyl ketone, and the like), esters (butyl acetate, dimethyl glutarate, triacetin, and the like), and polybasic acid solvents (glutaric acid and the like). In particular, it is preferable to use solvents having at least two ester bonds, for example, polybasic acid esters (for example, dimethyl glutarate) and acid esters of polyhydric alcohols (for example, triacetin). There is no particular limitation regarding the dispersing agent provided that the ceramic powder is dispersed in a solvent. Examples of the dispersing agent include polycarboxylic-acid-based copolymers, polycarboxylic acid salts, sorbitan fatty acid esters, polyglycerin fatty acid esters, phosphoric-acid-ester-salt-based copolymers, sulfonic-acid-salt-based copolymers, and tertiary-amine-containing-polyurethane-polyester-based copolymers. In particular, it is preferable to use polycarboxylic-acid-based copolymers, polycarboxylic acid salts, and the like. Using the dispersing agent enables the slurry before forming to have low viscosity and high fluidity. As described above, the ceramic slurry precursor is produced by adding the solvent and the dispersing agent to the ceramic powder in a predetermined ratio and performing mixing and disintegration for a predetermined time.

Subsequently, a molding agent (isocyanate and polyol) and a catalyst are added to the ceramic slurry precursor, and these are subjected to mixing and vacuum debubbling so as to produce a ceramic slurry. There is no particular limitation regarding the isocyanate provided that an isocyanate group is included as a functional group. For example, hexamethylene diisocyanate (HDI), tolylene diisocyanate (TDI), or diphenylmethane diisocyanate (MDI) or modified materials of these may be used. In this regard, a reactive functional group other than the isocyanate group may be included in the molecule, or a large number of reactive functional groups may be included as a polyisocyanate. There is no particular limitation regarding the polyol provided that a functional group capable of reacting with an isocyanate group, for example, a hydroxy group or an amino group, is included in the substance. For example, ethylene glycol (EG), polyethylene glycol (PEG), propylene glycol (PG), polypropylene glycol (PPG), polytetramethylene glycol (PTMG), polyhexamethylene glycol (PHMG), and polyvinyl butyral (PVB) may be used. There is no particular limitation regarding the catalyst provided that the substance facilitates a urethane reaction. For example, triethylenediamine, hexanediamine, 6-dimethylamino-1-hexanol, 1,5-diazacyclo(4,3,0)nonene-5,1,8-diazabicyclo[5,4,0]-7-undecene, dimethylbenzylamine, and hexamethyl tetraethylene tetramine may be used. The disc-forming portion 45 and the shaft-forming portion 46 are filled with the ceramic slurry injected through the injection port 40a of the forming die 40. Thereafter, a urethane resin serving as an organic binder is generated by a chemical reaction (urethane reaction) between the isocyanate and the polyol, and the ceramic slurry is cured by cross-linking adjacent urethane resin molecules so that urethane groups (—O—CO—NH—) generated in the molecules are connected to each other. The urethane resin functions as an organic binder. In this manner, the base formed body 30 is formed inside the forming die 40.

In this regard, there is no particular limitation regarding the mixing method for producing the ceramic slurry precursor or the ceramic slurry, and examples include ball mills, rotary and revolutionary agitation, vibrational agitation, propeller agitation, and static mixers. The size of the base formed body 30 is determined in consideration of the size of the ceramic heater 10 and shrinkage during firing. Meanwhile, a chemical reaction of the molding agent in the forming die 40 may generate gas, and the gas is readily discharged along the circular surface 45a (depressed surface) with an inclination angle θ relative to the outside. Consequently, gas bubbles do not remain in the base formed body 30.

Subsequently, the forming die 40 is turned upside down, the first lid 42 is removed so as to expose the upper surface of the unfired disc lower layer 32 of the base formed body 30 (refer to FIG. 5B), and the coil-like heater electrode 14 is fit into the heater electrode groove 33 (refer to FIG. 5C). The second lid 47 having a lower surface that protrudes downward is attached so as to form a space above the unfired disc lower layer 32 (refer to FIG. 5D). The resulting space is filled with the same ceramic slurry as above, and curing is caused by a chemical reaction so as to form an unfired disc middle layer 35 (refer to FIG. 5E). An RF electrode groove 35a is formed on the upper surface of the unfired disc middle layer 35. Thereafter, the second lid 47 is removed so as to expose the upper surface of the unfired disc middle layer 35 (refer to FIG. 5F), and a mesh-like RF electrode 16 is arranged in the RF electrode groove 35a (refer to FIG. 5G). The third lid 48 having a lower surface that protrudes downward is attached so as to form a space above the RF electrode 16 (refer to FIG. 5H). The resulting space is filled with the same ceramic slurry as above, and curing is caused by a chemical reaction so as to form an unfired disc upper layer 36 (refer to FIG. 51). The third lid 48, the bottom plate 43, and the circular column 44 are removed, the die main body 41 is taken apart, and the final formed body 50 is removed (refer to FIG. 5J). In the final formed body 50, the disc portion including the heater electrode 14 and the RF electrode 16 and the hollow shaft portion are integrally formed in a seamless state, and each of the upper surface and the lower surface of the disc portion has a shape in which the outer circumferential edge warps upward relative to the center portion. The height difference d between the center position of the circular surface and the position 150 mm distant from the center position outward in the radial direction is preferably 0.7 mm or more and 2.6 mm or less. Meanwhile, the inclination angle θ is preferably 0.25° or more and 1° or less.

2. Drying-Degreasing-Calcination Step

(1) Drying

The dispersing agent contained in the final formed body 50 is evaporated. The drying temperature and the drying time may be appropriately set in accordance with the type of the dispersion medium used. However, if the drying temperature is excessively high, cracking may be caused unfavorably. Meanwhile, the atmosphere may be air, an inert atmosphere, a vacuum, or a hydrogen atmosphere.

(2) Degreasing

The binder, the dispersing agent, and the catalyst contained in the final formed body 50 after the dispersion medium is evaporated are decomposed. The decomposition temperature may be, for example, 400° C. to 600° C., and the atmosphere may be air, an inert atmosphere, a vacuum, or a hydrogen atmosphere. However, in the case in which the electrode is embedded or a non-oxide-based ceramic is used, an inert atmosphere or a vacuum is adopted.

(3) Calcination

A calcined body 60 (refer to FIG. 6A) is obtained by heat-treating (calcining) the degreased final formed body 50 at 750° C. to 1,300° C. Calcination is performed to enhance the strength and to facilitate handling. The atmosphere may be air, an inert atmosphere, a vacuum, or a hydrogen atmosphere. However, in the case in which the electrode is embedded or a non-oxide-based ceramic is used, an inert atmosphere or a vacuum is adopted. In the calcined body 60, as in the final formed body 50, the disc portion including the heater electrode 14 and the RF electrode 16 and the hollow shaft portion are integrally formed in a seamless state, the disc portion has a shape in which the outer circumferential edge warps upward relative to the center portion, and the inclination angle θ is 0.25° or more and 1° or less. In this regard, after drying, degreasing and calcination may be performed in a single operation.

3. Firing Step

The ceramic heater 10 is obtained by firing the calcined body 60 while the calcined body 60 is arranged with the disc portion at the bottom and with the shaft portion at the top. The maximum temperature during the firing is appropriately set in accordance with the type of the powder and the particle diameter of the powder and is set within the range of preferably 1,000° C. to 2,000° C. In the calcined body 60, the disc portion having a shape in which the outer circumferential edge warps upward relative to the center portion becomes almost flat due to the firing. The atmosphere may be air, an inert atmosphere, or a vacuum. In this regard, to further suppress deformation during firing so as to make the disc portion flatter, as shown in FIG. 6A, it is preferable that the calcined body 60 with the disc portion at the bottom and with the shaft portion at the top be placed on a flat horizontal support plate 70 (for example, a plate formed of a BN material) and that atmospheric pressure firing be performed while a load is applied by placing a torus-shaped weight 72 on the disc portion. As a result, the ceramic heater 10 shown in FIG. 6B is obtained. If the weight of the weight 72 is excessively increased, cracking may occur because of an occurrence of a difference in shrinkage between the loaded disc portion and the free shaft portion. Therefore, appropriate setting within the range of 5 to 10 kg is preferable. In consideration of attachment and detachment, it is preferable that the weight 72 have a shape capable of being divided into at least two parts along the diameter.

In the ceramic heater 10 according to the present embodiment described above in detail, since the disc 12 and the shaft 20 are integrated without having a bonding interface, peeling at a bonding interface does not occur. Meanwhile, the ceramic heater 10 can be produced by firing the calcined body 60 only once (by subjecting to heat history once). Consequently, growth of sintered particles can be suppressed compared with the case in which the disc 12 and the shaft 20 undergo heat history twice, and, as a result, the strength can be enhanced.

In the forming die 40, the disc-forming portion 45 is in communication with the shaft-forming portion 46. Consequently, the base formed body 30 in which the unfired disc lower layer 32 and the unfired shaft 34 are integrated in a seamless state can be obtained by the ceramic slurry being injected into the forming die 40 and by the molding agent undergoing a chemical reaction in the forming die 40 so as to make the slurry into a mold. Since calcination and firing are performed after the heater electrode 14, the unfired disc middle layer 35, the RF electrode 16, and the unfired disc upper layer 36 are stacked on the unfired disc lower layer 32 of the base formed body 30 so as to form the final formed body 50, the ceramic heater 10 is obtained by performing firing once.

Further, according to the method for manufacturing the ceramic heater 10, the ceramic heater 10 in which the disc 12 and the shaft 20 are integrated without having a bonding interface can be readily obtained. In particular, in the forming die 40, since a pair of circular surfaces 45a and 45b constituting the disc-forming portion 45 are the above-described depressed surface and protruding surface, the base formed body 30 in which the unfired disc lower layer 32 and the unfired shaft 34 are integrated in a seamless state while being supported in an orientation with the unfired shaft 34 at the bottom and with the unfired disc lower layer 32 at the top makes the unfired disc lower layer 32 have a shape in which the outer circumferential edge warps upward relative to the center portion. Supporting and firing the calcined body 60 in the orientation with the unfired shaft 34 at the top during the firing step causes the disc 12 after firing to become an almost flat plane. Meanwhile, in the mold-casting method, gas may be generated when the molding agent undergoes a chemical reaction in the forming die 40. The resulting gas tends to be discharged to the outside along the depressed surface. Consequently, gas bubbles hardly remain in the base formed body 50. In particular, regarding each of the depressed surface and the protruding surface, when the height difference d is set to be 0.7 mm or more and 2.6 mm or less or when the inclination angle θ is set to be 0.25°θ1°, the disc lower layer after firing becomes a flatter plane.

Further, in the firing step, atmospheric pressure firing is performed while the weight 72 is placed on the disc portion of the calcined body 60. Consequently, the disc 12 becomes flatter and, in addition, deformation is further suppressed.

In this regard, it is needless to say that the present invention is not limited to the above-described embodiment and that the present invention can be realized in various forms within the technical scope of the invention.

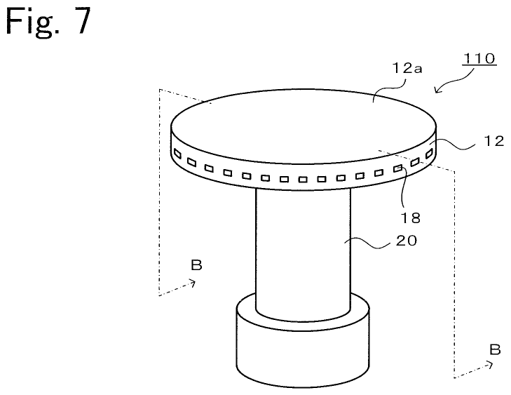

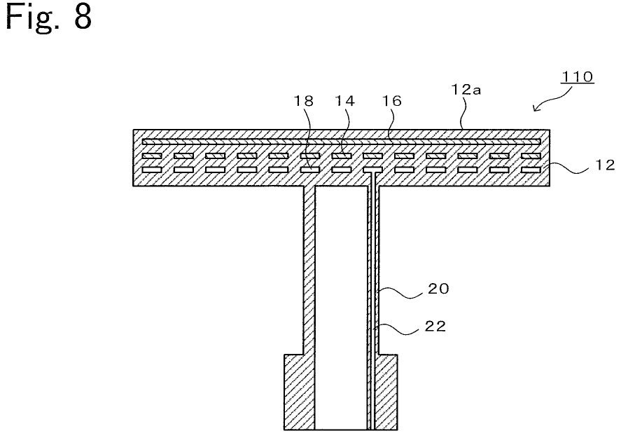

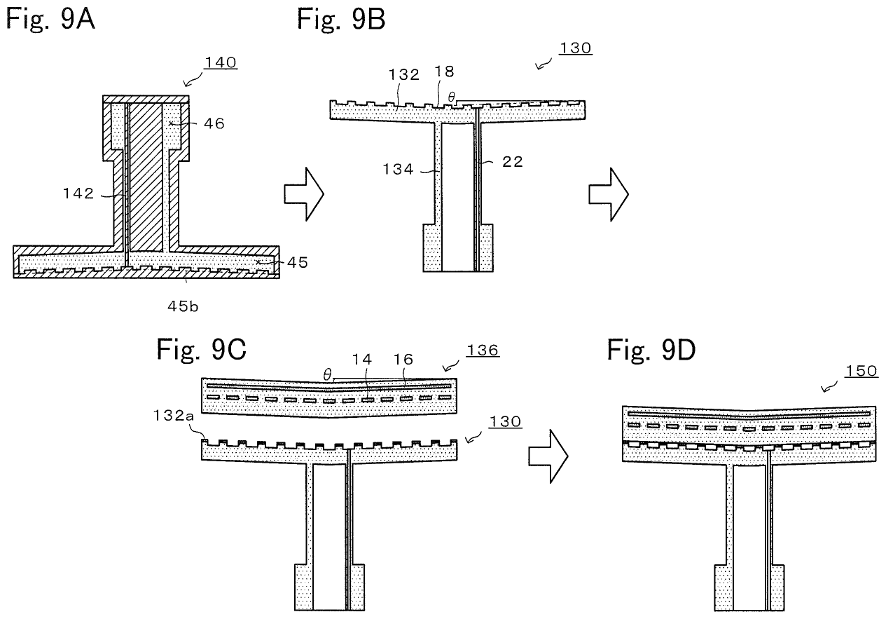

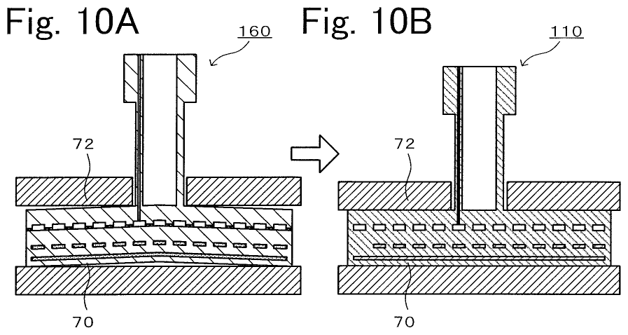

For example, as shown in FIG. 7 and FIG. 8, a gas channel 18 may be formed under the heater electrode 14 of the ceramic heater 10 according to the above-described embodiment. The ceramic heater 10 having the gas channel 18 is referred to as a ceramic heater 110. FIG. 7 is a perspective view of the ceramic heater 110. FIG. 8 is a sectional view cut along line B-B in FIG. 7. The gas channel 18 is a passage that extends lengthways and widthways parallel to the wafer placement surface 12a of the disc 12, and both ends open on the side surface of the ceramic heater 110. A gas feed passage 22 that extends in the vertical direction and that feeds gas to the gas channel 18 is formed in the circumferential wall of the shaft 20. When the wafer placed on the wafer placement surface 12a of the ceramic heater 110 is subjected to CVD film formation, etching, or the like by using plasma, ejecting the gas from the opening of the gas channel 18 to the side surface of the disc 12 through the gas feed passage 22 can suppress accumulations from adhering to the lower surface of the disc 12. To produce the ceramic heater 110, initially, a base formed body 130 shown in FIG. 9B is produced. The base formed body 130 has the same configuration as the base formed body 30 except that the gas channel 18 rather than the heater electrode groove 33 is formed on an unfired disc lower layer 132 and that the gas feed passage 22 is formed in the unfired shaft 134. Regarding each of the upper surface and the lower surface of the unfired disc lower layer 132, the height difference d between the center position and the position 150 mm distant from the center position outward in the radial direction is preferably 0.7 mm or more and 2.6 mm or less, or the inclination angle θ is preferably 0.25° or more and 1° or less. The base formed body 130 is formed by using a forming die 140 shown in FIG. 9A. The forming die 140 has the same configuration as the forming die 40 except that the circular surface 45b of the forming die 40 has a shape capable of forming the gas channel 18 and that a core rod member 142 is added to form the gas feed passage 22. The forming die 140 is arranged with the disc-forming portion 45 at the bottom and with the shaft-forming portion 46 at the top, the entire disc-forming portion 45 and the entire shaft-forming portion 46 are filled with a ceramic slurry injected through the injection port, and the slurry is cured so as to obtain the base formed body 130. Meanwhile, separately from the base formed body 130, a disc formed body 136 (refer to FIG. 9C) in which the heater electrode 14 and the RF electrode 16 are embedded is produced. To form the disc formed body 136, for example, in FIGS. 5A to 5J, production of the unfired shaft 34 of the calcined body 60 may be skipped, and the disc portion only may be produced. It is preferable that each of the upper surface and the lower surface of the disc formed body 136 also have the height difference d within the above-described numerical range or the inclination angle θ within the above-described numerical range. Subsequently, as shown in FIG. 9C, a portion excluding the gas channel 18 of the upper surface of the base formed body 130 is printed with an adhesive 132a, and the surface printed with the adhesive 132a is superposed on and bonded to the heater-electrode-14-side surface of the disc formed body 136. In this manner, a final formed body 150 shown in FIG. 9D is obtained. Regarding the adhesive, for example, a paste-like adhesive containing the same ceramic material as the disc 12 and the shaft 20, a binder, and a dispersing agent may be used. The final formed body 150 is subjected to drying, degreasing, and calcination so as to form a calcined body 160 in the same manner as the above-described embodiment, and, thereafter, the calcined body 160 is fired so as to obtain a ceramic heater 110. For example, as shown in FIGS. 10A and 10B, the ceramic heater 110 may be produced by placing the calcined body 160 with the disc portion at the bottom and with the shaft portion at the top on a flat horizontal support plate 70 (for example, a plate formed of a BN material), and by performing atmospheric pressure firing while a load is applied by placing the torus-shaped weight 72 on the disc. In the ceramic heater 110, since the disc 12 and the shaft 20 are integrated without having a bonding interface, peeling at a bonding interface does not occur. Meanwhile, the ceramic heater 110 can be produced by firing the calcined body 160 only once (by subjecting to heat history once). Consequently, growth of sintered particles can be suppressed compared with the case in which the disc 12 and the shaft 20 undergo heat history twice, and, as a result, the strength can be enhanced.

In the above-described embodiment, the example in which both the heater electrode 14 and the RF electrode 16 are included in the disc 12 is shown. However, only one of these may be included in the disc 12. Meanwhile, an electrostatic electrode instead of the electrodes 14 and 16 may be included in the disc 12. This also applies to the ceramic heater 110.

In the above-described embodiment, the circular surface 45a of the forming die 40 is set to be a depressed surface that is depressed in the form of a circular cone and the circular surface 45b is set to be a protruding surface that protrudes in the form of a circular cone. However, the circular surface 45a may be set to be a depressed surface that is depressed in the form of a circular truncated cone and the circular surface 45b may be set to be a protruding surface that protrudes in the form of a circular truncated cone. Alternatively, the circular surface 45a may be set to be a depressed surface that is depressed in the form of a curved surface and the circular surface 45b may be set to be a protruding surface that protrudes in the form of a curved surface. This also applies to the forming die 140.

In the above-described embodiment, the coil-like heater electrode 14 is fit into the heater electrode groove 33, and the mesh-like RF electrode 16 is fit into the RF electrode groove 35a. However, such grooves 33 and 35a may be skipped, and an electrode pattern may be formed by screen printing or the like in which an electrode paste is used. The electrode pattern may be formed on the surface of the formed body, or the electrode pattern may be disposed in advance on the inner surface of the forming die before producing the formed body and may be attached to the formed body during production of the formed body. The electrode paste is prepared so as to contain, for example, a conductive material, a ceramic material, a binder, and a dispersion medium. Examples of the conductive material include tungsten, tungsten carbide, platinum, silver, palladium, nickel, molybdenum, ruthenium, and aluminum or compounds of these substances. Regarding the binder, for example, polyethylene glycol (PEG), propylene glycol (PG), polypropylene glycol (PPG), polytetramethylene glycol (PTMG), polyhexamethylene glycol (PHMG), polyvinyl butyral (PVB), and acrylic resins may be used. Regarding the dispersing agent and the dispersion medium, the same materials as the molding agent may be used. This also applies to the ceramic heater 110.

In the above-described embodiment, the inclination angle θ of each of the upper surface and the lower surface of the unfired disc lower layer 32 of the base formed body 30 is set to be 0.25° or more and 1° or less. However, the inclination angle θ may be an angle beyond the above-described range (for example, 0° or 2°. In this case, the wafer placement surface 12a of the ceramic heater 10 does not become as flat as in the above-described embodiment, but peeling at a bonding interface does not occur since the disc 12 and the shaft 20 are integrated without having a bonding interface. In this case, since the calcined body can be produced by undergoing heat history once, growth of sintered particles can be suppressed compared with the case in which the disc 12 and the shaft 20 undergo heat history twice, and, as a result, the strength can be enhanced. This also applies to the ceramic heater 110.

In the above-described embodiment, a fired body may be produced by performing firing in the same manner as the above-described firing step at any of the stage of the base formed body 30 (refer to FIG. 5B), the stage at which the heater electrode 14 is attached to the base formed body 30 (refer to FIG. 5C), the stage at which the heater electrode 14 and the unfired disc middle layer 35 are stacked on the base formed body 30 (refer to FIG. 5F), and the stage at which the heater electrode 14, the unfired disc middle layer 35, and the RF electrode 16 are stacked on the base formed body 30 (refer to FIG. 5G), and remaining portions may be produced individually and connected to the fired body.

In the above-described embodiment, the cylindrical member is used as the shaft 20. However, a solid cylindrical member may be used.

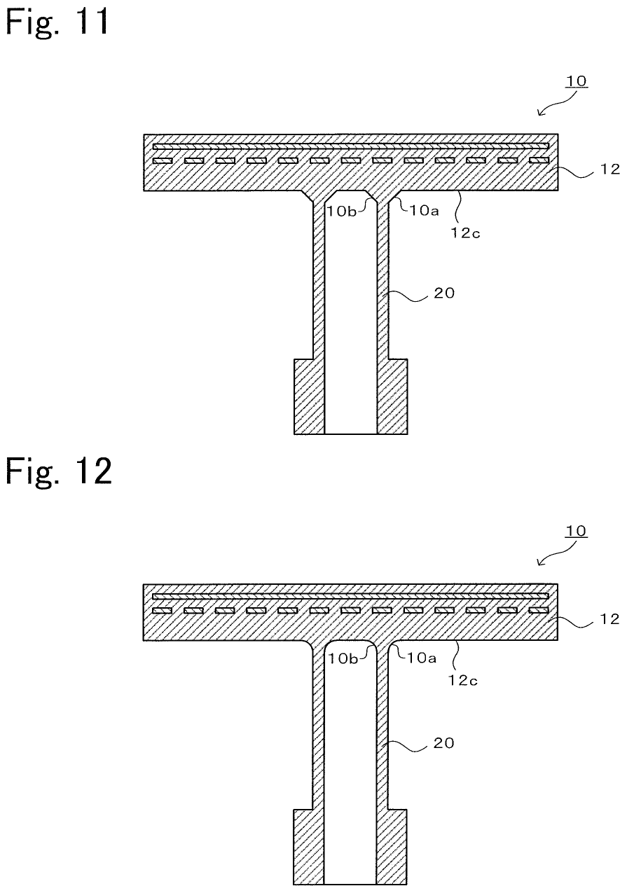

In the ceramic heater 10 of the above-described embodiment, as shown in FIG. 12, a boundary portion 10a between the outer surface of the shaft 20 and the back surface 12c of the disc 12 with which the shaft 20 is integrated and a boundary portion 10b between the inner surface of the shaft 20 and the back surface 12c of the disc 12 may be an R-surface (curved surface having a predetermined radius of curvature). Alternatively, as shown in FIG. 11, boundary portions 10a and 10b may be tapered surfaces. As a result, stress applied to the boundary portions 10a and 10b can be relaxed. When the ceramic heater 10 in which the boundary portions 10a and 10b are an R-surface or a tapered surface is produced, in the forming die 40 shown in FIG. 4, the portions corresponding to the boundary portions 10a and 10b may be made into the R-surface or the tapered surface. Meanwhile, one of the boundary portions 10a and 10b may be an R-surface and the other may be right angled, one of the boundary portions 10a and 10b may be a tapered surface and the other may be right angled, or one of the boundary portions 10a and 10b may be an R-surface and the other may be a tapered surface. This also applies to the ceramic heater 110.

### EXAMPLES

In experimental examples A1 to A8 described below, the ceramic heater 10 was produced, and in experimental example A9, the same ceramic heater as the ceramic heater 10 was produced. Meanwhile, in experimental examples B1 to B2, the ceramic heater 110 was produced, and in experimental example B3, the same ceramic heater as the ceramic heater 110 was produced.

### Experimental Example A1

1. Forming Step

A ceramic slurry precursor was obtained by mixing 100 parts by mass of aluminum nitride powder (purity of 99.7%), 5 parts by mass of yttrium oxide, 2 parts by mass of dispersing agent (polycarboxylic-acid-based copolymer), and 30 parts by mass of dispersion medium (polybasic acid ester) for 14 hours by using a ball mill (trommel). A ceramic slurry was obtained by adding 4.5 parts by mass of isocyanate (4,4′-diphenylmethane diisocyanate), 0.1 parts by mass of water, and 0.4 parts by mass of catalyst (6-dimethylamino-1-hexanol) to the resulting ceramic slurry precursor and by performing mixing. A final formed body 50 was obtained following the procedure shown in FIGS. 5A to 5J by using the resulting ceramic slurry. The inclination angle θ of the forming die 40 was set to be 0.5°. The height difference d between the center position of the circular surface of the forming die 40 and the position 150 mm distant from the center position outward in the radial direction was 1.3 mm. In this regard, a Mo coil was used as the heater electrode 14, and a Mo mesh was used as the RF electrode 16.

2. Drying-Degreasing-Calcination Step

The resulting final formed body 50 was dried at 100° C. for 10 hours, degreased at a maximum temperature of 500° C., and calcined at a maximum temperature of 820° C. in a nitrogen atmosphere so as to obtain a calcined body 60.

3. Firing Step

As shown in FIGS. 6A and 6B, the calcined body 60 with the disc portion at the bottom and with the shaft portion at the top was placed on a flat horizontal support plate 70 formed of a BN material, and atmospheric pressure firing was performed in nitrogen gas at 1,860° C. for 6 hours while a load was applied by placing a torus-shaped weight 72 (10 kg) on the disc portion. As a result, the ceramic heater 10 (diameter of the disc 12 of 300 mm) was obtained.

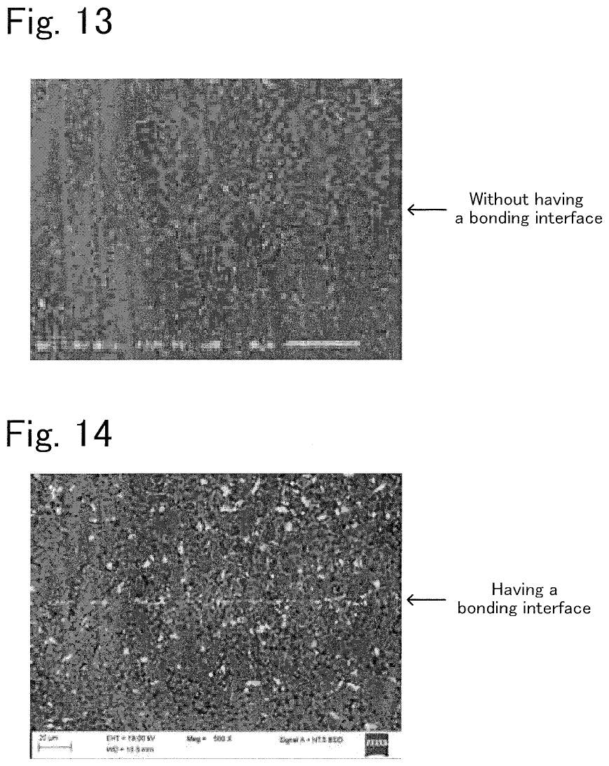

Regarding the ceramic heater 10 of experimental example 1, as shown in Table 2, the strength was 330 MPa, the average particle diameter was 4.2 μm, and the warp after firing was 0.05 mm. Gas bubbles were not observed in the final formed body 50. In this regard, the strength measurement was in conformity with JIS: 1601, and a test piece was cut so as to include the connection portion between the disc 12 and the shaft 20. The test piece was set to be a rectangular parallelepiped with a width W of 4.0 mm, a thickness t of 3.0 mm, and a length of 40 mm. The test piece was placed on two fulcrums arranged at a predetermined distance such that the connection portion was located at the center between the fulcrums, a load was divided into two parts and applied to respective points located at an equal distance from the center between the fulcrums in the lateral direction opposite to each other, and a maximum bending stress at the time when the test piece was folded was measured. Regarding the average particle diameter, the average of the major axis and the minor axis of the particle observed with an SEM was denoted as a particle diameter, and the average of the particle diameters of 40 particles observed was denoted as the average particle diameter. The warp was denoted as the difference between the maximum value and the minimum value of the height of the wafer placement surface 12a. Presence or absence of gas bubble was determined by visually observing a cross section of the final formed body 50. In this regard, as indicated by an SEM image (magnification of 500 times, reflection electron image) in FIG. 13, the ceramic heater 10 of experimental example A1 was integrated such that the bonding interface between the disc-like fired body and the tubular fired body could not be identified. Regarding the SEM image, a secondary electron image may be used.

### Experimental Examples A2 to A7

In each of experimental examples A2 to A7, the ceramic heater 10 was produced in the same manner as in experimental example A1 except that the inclination angle θ and the height difference d of experimental example A1 were changed. In the ceramic heater 10 of each of experimental examples A2 to A7, the disc 12 and the shaft 20 were integrated without having a bonding interface as in experimental example A1. The inclination angle θ, the height difference d, the firing method, the strength, the average particle diameter, the warp after firing, and presence or absence of gas bubble of each of experimental examples A2 to A7 are collectively shown in Table 2.

### Experimental Example A8

1. Forming Step

A ceramic slurry precursor was prepared in the same manner as in experimental example A1. A ceramic slurry was obtained by adding 4.5 parts by mass of isocyanate (hexamethylene diisocyanate), 0.1 parts by mass of water, and 0.4 parts by mass of catalyst (6-dimethylamino-1-hexanol) to the resulting ceramic slurry precursor and by performing mixing. A final formed body 50 was obtained following the procedure shown in FIGS. 5A to 5J by using the resulting ceramic slurry. The inclination angle θ of the forming die 40 was set to be 0.5°, and the height difference d was set to be 1.3 mm. The heater electrode 14 and the RF electrode 16 were formed by screen printing using a Mo paste (containing aluminum nitride powder (purity of 99.7%)). Therefore, the heater electrode groove 33 and the RF electrode groove 35a were skipped.

2. Drying-Degreasing-Calcination Step

The resulting final formed body 50 was dried at 100° C. for 10 hours, and degreased and calcined at a maximum temperature of 1,300° C. in a hydrogen atmosphere so as to obtain a calcined body 60.

3. Firing Step

The ceramic heater 10 of experimental example A8 was obtained by performing firing in the same manner as in experimental example A1. The characteristics thereof are shown in Table 2. Regarding the ceramic heater 10, a bonding interface was not observed as in experimental example A1.

### Experimental Example A9

1. Forming Step

After 5% by mass of yttrium oxide serving as a sintering aid was added to 95% by mass of aluminum nitride powder, mixing was performed by using a ball mill. A binder was added to the resulting mixed powder, and granulation was performed by using a spray granulation method. The resulting granulation powder was degreased, and a disc-like formed body and a tubular formed body were formed by die forming and CIP. A Mo mesh serving as the RF electrode and a Mo coil serving as the heater electrode were embedded inside the disc-like formed body.

2. Firing Step

The disc-like formed body was fired in nitrogen gas at 1,860° C. for 6 hours by using a hot-press method so as to produce a disc-like fired body. Separately from this, the tubular formed body was fired in nitrogen gas at 1,860° C. for 6 hours by using atmospheric pressure firing so as to produce a tubular fired body.

3. Bonding Step

The bonding interface between the disc-like fired body and the tubular fired body was coated with yttrium nitrate, and drying was performed at 100° C. for 1 hour. Subsequently, the disc-like fired body and the tubular fired body were heat-treated to be bonded to each other by using a bonding method described in example 1 of Japanese Unexamined Patent Application Publication No. 2006-232576 so as to obtain a ceramic heater of experimental example A9. The characteristics thereof are shown in Table 2. In this regard, as indicated by an SEM image in FIG. 14, the ceramic heater of experimental example A9 was integrated such that the bonding interface between the disc-like fired body and the tubular fired body could be identified.

TABLE 2

| | | | | | Average | Warp | |
|---|---|---|---|---|---|---|---|
| | | | | | particle | after | Presence or |
| Experimental | θ | d | Performing | Strength | diameter | firing | absence of |
| Example | (°) | (mm) | firing | (MPa) | (μm) | (mm) | gas bubble |
| A1 | 0.5 | 1.3 | Atmospheric | 330 | 4.2 | 0.05 | Not |
| | | | pressure firing (With weight) | | | | observed |
| A2 | 0 | 0 | Atmospheric | - | - | 0.5 | Observed |
| | | | pressure firing (With weight) | | | | |
| A3 | 0.25 | 0.7 | Atmospheric | - | - | 0.03 | Not |
| | | | pressure firing (With weight) | | | | observed |
| A4 | 1 | 2.6 | Atmospheric | - | - | 0.08 | Not |
| | | | pressure firing (With weight) | | | | observed |
| A5 | 2 | 5.2 | Atmospheric | - | - | 0.5 | Not |
| | | | pressure firing (With weight) | | | | observed |
| A6 | 3 | 7.9 | Atmospheric | - | - | 2.5 | Not |
| | | | pressure firing (With weight) | | | | observed |
| A7 | 4 | 10.5 | Atmospheric | - | - | 5.5 | Not |
| | | | pressure firing (With weight) | | | | observed |
| A8 | 0.5 | 1.3 | Atmospheric | 340 | 4.2 | 0.04 | - |
| | | | pressure firing (With weight) | | | | |

| | | | | | |
|---|---|---|---|---|---|
| A9 | Conventional Example | 300 | 4.7 | 0.12 | - |

※ In Table 2, a hyphen (-) indicates that a measurement is not performed.

As is clear from the results of experimental examples A1 to A7 shown in Table 2, it was found that the inclination angle θ being 0.25° or more and 1° or less (height difference d being 0.7 mm or more and 2.6 mm or less) reduced the warp compared with the case in which the inclination angle θ is 0° (height difference d was 0 mm). Meanwhile, in the case in which the inclination angle θ (height difference d) was provided as in experimental examples A1 and A3 to A7, gas bubbles were not observed in the final formed body 50. Further, regarding each of experimental examples A1 and A8, the average particle diameter was small compared with experimental example A9, and the strength was high. It is considered that since the disc-like fired body and the tubular fired body in experimental example A9 were bonded by re-firing, the bonding interface could be identified and growth of sintered particles advanced so as to reduce the strength. Meanwhile, it is considered that since the calcined body 60 with the disc portion and the shaft portion in a seamless state was fired only once in each of experimental examples A1 and A8, the bonding interface was not observed, growth of sintered particles could be suppressed, and, as a result, the strength could be enhanced. In this regard, since the ceramic heater 10 of each of experimental examples A2 to A7 was produced in the same manner as in experimental example A1 except that the inclination angle θ and the height difference d were changed, it is considered that the strength and the average particle diameter are substantially equal to those in experimental example A1.

### Experimental Example B1

A final formed body 150 was produced following FIGS. 9A to 9D, and the resulting final formed body 150 was calcined so as to produce a calcined body 160. Thereafter, a ceramic heater 110 of experimental example B1 was produced following FIGS. 10A and 10B. The ceramic slurry in the forming step was prepared in the same manner as in experimental example A1. In addition, the conditions for the drying-degreasing-calcination step and the firing step were the same as in experimental example A1. Regarding the adhesive, a paste in which an aluminum nitride powder, an acrylic resin serving as a binder, and terpineol serving as a dispersion medium were mixed was used. The characteristics thereof are shown in Table 3. Regarding the resulting ceramic heater 110, the bonding interface was not observed.

### Experimental Example B2

A final formed body 150 was produced following FIGS. 9A to 9D, and the resulting final formed body 150 was calcined so as to produce a calcined body 160. Thereafter, a ceramic heater 110 of experimental example B2 was produced following FIGS. 10A and 10B. The ceramic slurry in the forming step was prepared in the same manner as in experimental example A8. In addition, the conditions for the drying-degreasing-calcination step and the firing step were the same as in experimental example A8. Regarding the adhesive, a paste in which an aluminum nitride powder, an acrylic resin serving as a binder, and terpineol serving as a dispersion medium were mixed was used. The characteristics thereof are shown in Table 3. Regarding the resulting ceramic heater 110, the bonding interface was not observed.

### Experimental Example B3

1. Forming Step

After 5% by weight of yttrium oxide serving as a sintering aid was added to 95% by weight of aluminum nitride powder, mixing was performed by using a ball mill. A binder was added to the resulting mixed powder, and granulation was performed by using a spray granulation method. The resulting granulation powder was degreased, and a disc-like formed body and a tubular formed body were formed by die forming and CIP. Regarding the disc-like formed body, a first disc-like formed body in which the heater electrode (Mo coil) was embedded and a second disc-like formed body in which the RF electrode (mesh electrode) was embedded were produced.

2. Firing Step

The first disc-like formed body and the second disc-like formed body were individually fired in nitrogen gas at 1,860° C. for 6 hours by using a hot press method so as to produce a first disc-like fired body and a second disc-like fired body, respectively. Meanwhile, the tubular formed body was fired in nitrogen gas at 1,860° C. for 6 hours by using atmospheric pressure firing so as to produce a tubular fired body.

3. Bonding Step

The bonding interfaces between the first disc-like fired body, the second disc-like fired body, and the tubular fired body were coated with an yttrium nitrate, and drying was performed at 100° C. for 1 hour. Subsequently, the first disc-like fired body, the second disc-like fired body, and the tubular fired body were heat-treated to be bonded to each other by using a bonding method described in example 1 of Japanese Unexamined Patent Application Publication No. 2006-232576 so as to obtain a ceramic heater of experimental example B3. The characteristics thereof are shown in Table 3. In this regard, the ceramic heater of experimental example B3 was integrated such that the bonding interfaces between the first disc-like fired body, the second disc-like fired body, and the tubular fired body could be identified with an SEM.

TABLE 3

| | | | | | Average | Warp |
|---|---|---|---|---|---|---|
| | | | | | particle | after |
| Experimental | θ | d | Performing | Strength | diameter | firing |
| Example | (°) | (mm) | firing | (MPa) | (μm) | (mm) |
| B1 | 0.5 | 1.3 | Atmospheric | 331 | 4.1 | 0.06 |
| | | | pressure firing (With weight) | | | |
| B2 | 0.5 | 1.3 | Atmospheric | 335 | 4.2 | 0.05 |
| | | | pressure firing (With weight) | | | |

| | | | | |
|---|---|---|---|---|
| B3 | Conventional Example | 305 | 4.7 | 0.13 |

As is clear from Table 3, regarding each of experimental examples B1 and B2, warp was reduced compared with experimental example B3. In addition, regarding each of experimental examples B1 and B2, the average particle diameter was small compared with experimental example B3, and the strength was high. It is considered that since the first disc-like fired body, the second disc-like fired body, and the tubular fired body in experimental example B3 were bonded by heat treatment, the bonding interface could be identified and growth of sintered particles advanced so as to reduce the strength. Meanwhile, it is considered that since the calcined body 160 with the disc portion and the shaft portion in a seamless state was fired only once in each of experimental examples B1 and B2, the bonding interface was not observed, growth of sintered particles could be suppressed, and, as a result, the strength could be enhanced.

Of the above-described experimental examples, experimental examples A1 to A8 and experimental examples B1 and B2 correspond to the examples of the present invention, and experimental example A9 and experimental example B3 correspond to the comparative examples. In this regard, the above-described experimental examples do not limit the present invention.

The present invention contains subject matter related to Japanese Patent Application No. 2017-212932 filed on Nov. 2, 2017, the entire contents of which are incorporated herein by reference.

What is claimed is:

1. A semiconductor manufacturing device member comprising a ceramic disc with an internal electrode and a ceramic shaft that supports the disc,
wherein the disc and the shaft are integrated without having a bonding interface.

2. The semiconductor manufacturing device member according to claim 1,
wherein the electrode is at least one of a heater electrode, an RF electrode, and an electrostatic electrode.

3. The semiconductor manufacturing device member according to claim 1,
wherein the disc has a gas channel that opens on the side surface of the disc and that is formed in the plate surface direction of the disc, and the shaft has a gas feed passage that extends in the vertical direction and that feeds a gas to the gas channel.

4. The semiconductor manufacturing device member according to claim 1,
wherein a boundary portion between the outer surface of the shaft and the surface of the disc with which the shaft is integrated is an R-surface or a tapered surface.

5. The semiconductor manufacturing device member according to claim 1,
wherein the shaft is a cylindrical member, and
a boundary portion between the inner surface of the shaft and the surface of the disc with which the shaft is integrated is an R-surface or a tapered surface.

6. A forming die used for producing the semiconductor manufacturing device member according to claim 1, comprising:
a disc-forming portion that is a space for forming a disc lower layer on the shaft side of the disc, and
a shaft-forming portion that is in communication with the disc-forming portion and that is a space for forming the shaft.

7. The forming die according to claim 6,
wherein the disc-forming portion is a space surrounded by a pair of circular surfaces and an outer circumferential surface connected to the pair of circular surfaces, and
the shaft-forming-portion-side circular surface of the pair of circular surfaces is a depressed surface that is depressed toward the shaft-forming portion and the circular surface opposite to the shaft-forming portion of the pair of circular surfaces is a protruding surface that protrudes toward the shaft-forming portion.

8. The forming die according to claim 7,
wherein regarding each of the depressed surface and the protruding surface, the height difference d between the center position and the position 150 mm distant from the center position outward in the radial direction is 0.7 mm or more and 2.6 mm or less.

9. The forming die according to claim 7, wherein the inclination angle θ of each of the depressed surface and the protruding surface is 0.25°≤θ≤1°.

10. The forming die according to claim 7,
wherein the depressed surface is a surface that is depressed toward the shaft-forming portion in the form of a circular cone or a circular truncated cone, and the protruding surface is a surface that protrudes toward the shaft-forming portion in the form of a circular cone or a circular truncated cone.

11. A method for manufacturing a semiconductor manufacturing device member comprising the steps of:
(a) producing, by using the forming die according to claim 6, a base formed body in which an unfired disc lower layer formed in the disc-forming portion and an unfired shaft formed in the shaft-forming portion are integrated in a seamless state by using a mold-casting method;
(b) obtaining a final formed body by stacking an unfired disc upper layer provided with an electrode or a precursor of the electrode parallel to the unfired disc lower layer on the upper surface of the unfired disc lower layer of the base formed body; and
(c) obtaining a semiconductor manufacturing device member in which the disc and the shaft are integrated without having a bonding interface by calcining the final formed body, and, thereafter, firing the resulting final formed body in the state of being mounted with the unfired disc upper layer at the bottom and with the unfired shaft at the top on a horizontal support surface.

12. The method for manufacturing a semiconductor manufacturing device member according to claim 11,
wherein, in step (a) above, a gas channel is formed on the upper surface of the unfired disc lower layer so as to open on the side surface during production of the base formed body by using the mold casting method, and
in step (b) above, the final formed body is obtained by bonding the unfired disc upper layer above the gas channel.
